(19) United States
(12) Patent Application Publication
(10) Pub. No.: US 2015/0102816 A1
(43) Pub. Date: Apr. 16, 2015

(54) Apparatus And Method For Identifying Batteries Of Different Thicknesses, And Electronic Device

(71) Applicants: Kai Ma, Shenzhen City (CN); Jianmin Fang, Shenzhen City (CN)

(72) Inventors: Kai Ma, Shenzhen City (CN); Jianmin Fang, Shenzhen City (CN)

(73) Assignee: ZTE CORPORATION, Shenzhen City, Guangdong Province (CN)

(21) Appl. No.: 14/396,279

(22) PCT Filed: Jun. 29, 2012
(86) PCT No.: PCT/CN2012/077846

§ 371 Date: Dec. 29, 2014

(30) Foreign Application Priority Data
May 22, 2012 (CN) 201210162828.8

(51) Int. Cl. G01R 31/36; H01H 3/16; H01H 1/44; H01H 1/06

(52) U.S. Cl. CPC G01R 31/3665; H01H 1/06; H01H 3/16; H01H 1/44
USPC 324/426

(57) ABSTRACT

An apparatus and method for identifying batteries with different thickness, and an electronic device thereof, the apparatus comprises a buckle switch arranged at a position close to battery compartment in the electronic device, and a control circuit connected with the buckle switch. When a thin battery is mounted in the electronic device, the state of the buckle switch is ON; and when a thick battery is mounted in the electronic device, the state of the buckle switch is OFF. According to the ON/OFF state of the buckle switch, the control circuit identifies whether a thin battery or a thick battery is mounted in the electronic device. The apparatus and method can identify whether a thin battery or a thick battery is used in the electronic device, and thereby can adopt different drivers to manage the battery.

### CLAIM FOR PRIORITY AND CROSS-REFERENCE TO RELATED APPLICATION

This application is the US National Phase application of PCT application number PCT/CN2012/077846 having a PCT filing date of Jun. 29, 2012, which claims priority of Chinese patent application 201210162828.8 filed on May 22, 2012, the disclosures of which are hereby incorporated by reference.

### TECHNICAL FIELD

The present invention relates to the field of rechargeable battery technology used by electronic devices, and more particularly, to an apparatus and method for identifying batteries with different thicknesses, and an electronic device thereof.

### BACKGROUND OF THE INVENTION

Currently, the market demands for portable electronic devices such as mobile terminals, laptops and tablet PCs that use rechargeable batteries as power source develop rapidly, and these electronic devices have more and more functions and applications, which results in more and more power consumption, and the devices' demand for battery capacity is growing. However, due to limitations of the existing battery technology, the battery capacity is often proportional to the battery volume. The power sustainability and portability of the devices are hard to co-exist, which results in that many electronic devices are equipped with two or even more sets of optional batteries, and in the same battery slot of the device, it needs to use batteries with different capacity and volume corresponding to the different needs. Such applications also bring in some problems, such as identifying batteries with different capacities, computing battery power, displaying the battery status, and so on.

Lithium batteries have advantages such as large storage capability, long life, lightweight, and no memory effect, and it has been widely used in existing portable devices. mAh is the measuring unit of battery capacity, specifically is the total number of electronics that can be released by the battery for external use, and it is equivalent to the physical standard unit: Coulomb. The international standard unit of Coulomb is ampere second which is obtained by multiplying current with time, 1 mAh=0.001 Ampere*3600 seconds=3.6 ampere seconds=3.6 Coulomb.

In conventional electronic devices, there are the following three methods for calculating the battery power:

1. direct battery voltage monitoring method: the direct battery voltage monitoring method is simple and easy to implement; however, this method has low accuracy (20%), and it cannot effectively protect the battery;

2. battery modeling method: the battery modeling method effectively improves the power measurement accuracy (5%), it is easy to use and does not need to perform an initial estimate of the battery; however, the establishment of the data table is a complex process, and it has not good compatibility with batteries with different capacities or types;

3. coulometer detection method: the coulometer can accurately track the battery power change, and its accuracy can be up to 1%; however, the coulometer has the problem in initial estimate of the battery, it needs to know the rated capacity, the current capacity and present current loss, moreover, the precision of the current resistor directly affects the accuracy of battery power.

At present, the coulometer detection is the most accurate and effective method, and most of the popular smart mobile terminals, tablet computers and other electronic devices use coulometer detection method, however, the coulometer detection method can only solve problems of power computation and power display of batteries with a fixed capacity, while for batteries with different capacity, the coulometer detection method cannot calculate and display battery power accurately. Therefore, how to achieve a simple, fast and accurate identification of batteries with different capacities is currently a technical problem to be solved.

### SUMMARY OF THE INVENTION

The purpose of the embodiments of the present invention is to provide an apparatus and method for identifying batteries with different thicknesses, and an electronic device thereof, to identify whether a thin battery or a thick battery is used in said electronic device, and further use different drivers to manage said battery.

Said apparatus for identifying batteries with different thicknesses in accordance with an embodiment of the present invention comprises a buckle switch arranged at a position close to a battery compartment in an electronic device and a control circuit connected with said buckle switch;

said buckle switch being configured to: when a thin battery is mounted in said electronic device, said buckle switch's state is ON; when a thick battery is mounted in said electronic device, the state is OFF;

said control circuit being configured to: according to the state of ON/OFF of said buckle switch, identify whether a thin battery or a thick battery is mounted in said electronic device.

Alternatively, said buckle switch comprises a buckle, a spring member and a switch device, and said buckle is configured to be inserted into a housing of said electronic device by slotting, an arc-shaped contact surface is provided on one side of said battery compartment that is close to said buckle, and a slot is provided on the other side; said spring member is connected to said slot and said switch device respectively;

said buckle switch is configured as:

when a battery is loaded into said battery compartment, said battery contacting with said arc-shaped contact surface on one side of said buckle, and squeezing said spring member on the other side of said buckle; wherein, when the thick battery is loaded into said battery compartment, said buckle is pressed down, and said spring member is squeezed to trigger said slot to press said switch device down; when the thin battery is loaded into said battery compartment, said buckle is not pressed down, and a force of said spring member drives said switch device to pop up.

Alternatively, said control circuit comprises a baseband processing chip, and said buckle switch is connected with a general purpose input output (GPIO) port of said baseband processing chip, and said baseband processing chip is configured to determine the state of said buckle switch being ON or OFF according to a level state of said GPIO port.

Alternatively, a number of said buckles and said spring members is one or more.

Alternatively, said control circuit is further configured to, after identifying the battery mounted in said electronic device, respectively call appropriate power management modules to calculate and/or display power of said electronic device's power supply.

Alternatively, said switch device comprises: a mechanical press-contact switch, a flexible printed circuit (FPC) switch, or a stylus switch.

Alternatively, said switch device is configured as:

being welded on said motherboard;

alternatively, an elastic pin on said switch device being pressed to touch a metal contact point of said motherboard;

alternatively, a metal contact point of said switch device being pressed and touched by an elastic pin set on said motherboard.

Furthermore, the method for identifying batteries with different thicknesses in accordance with an embodiment of the present invention comprises:

arranging a buckle switch connected with a control circuit at a position close to a battery compartment in an electronic device;

when a thin battery is mounted in said electronic device, a state of said buckle switch being ON; when a thick battery is mounted in said electronic device, the state of said buckle switch being OFF;

according to the state of ON/OFF of said buckle switch, said control circuit identifying whether a thin battery or a thick battery is mounted in said electronic device.

Alternatively, said control circuit comprising a baseband processing chip, and said buckle switch being connected with a GPIO port of said baseband processing chip, and said baseband processing chip determining the state of said buckle switch being ON or OFF according to a level state of said GPIO port.

Alternatively, said buckle switch comprises a buckle, a spring member and a switch device, and said buckle is fitted in a housing of said electronic device by slotting, one side of the buckle that is close to said battery compartment is provided with an arc-shaped contact surface, and the other side is provided with a slot; said spring member is respectively connected with said slot and said switch device;

when said battery is loaded into said battery compartment, said battery contacts with said arc-shaped contact surface on one side of said buckle, and squeezes said spring member on the other side of said buckle;

wherein, when the thick battery is loaded into said battery compartment, said buckle is pressed down, said spring member is squeezed and triggers said slot to press said switch device down; when a thin battery is loaded into said battery compartment, said buckle is not pressed down, and a force of said spring member drives said switch device to pop up.

Alternatively, said switch device is welded on said motherboard;

alternatively, a metal contact point is disposed on said motherboard, and an elastic pin on said switch device is pressed to touch said metal contact point;

alternatively, an elastic pin is set on said motherboard, and said elastic pin is pressed to touch a metal contact point of said switch device.

Alternatively, the method further comprises:

after said control circuit identifies the battery mounted in said electronic device, respectively calling appropriate power management modules to calculate and/or display power of said electronic device's power supply.

The embodiment of the present invention further provides an electronic device, comprising the abovementioned apparatus.

Compared with the prior art, the embodiments of the present invention have at least the following advantages:

1. simply and accurately judging the battery type, having a low cost, having a relatively simple implementation, and it is simple, easy to implement;

2. reducing the cost, structural members (comprising rear housing, battery cover, and so on) do not need to change when using thick and think two batteries, and they can share one set of structural members;

3. the buckle switch can play the function of fixing the battery, when using a battery with different thickness, the battery does not shift, thus the whole user experience is good;

4. the type of battery can be automatically identified and managed without the user separately processing and selecting a program, thus the user experience is good.

### BRIEF DESCRIPTION OF THE DRAWINGS

The accompanying drawings described herein are used to provide a further understanding of the embodiments of the present invention, and constitute a part of the present application, exemplary embodiments of the present invention and their description are used to explain the present invention and do not constitute an unduly limit of the present invention. In the accompanying drawings:

FIG. 1a and FIG. 1b are respectively schematic diagrams of mounting batteries with two different thicknesses in an electronic device;

FIG. 2 is a schematic diagram of a control circuit of a buckle switch in accordance with an embodiment of present invention;

FIG. 3 is an exploded view of a mobile terminal with a buckle switch in accordance with an embodiment of the present invention;

FIG. 4 is a schematic diagram of a buckle switch in accordance with an embodiment of the present invention;

FIG. 5a and FIG. 5b are respectively schematic diagrams of internal assemblies of a mobile terminal with a buckle switch in accordance with an embodiment of the present invention;

FIG. 6a and FIG. 6b are respectively schematic diagrams of battery assemblies of a mobile terminal with a buckle switch in accordance with an embodiment of the present invention.

### PREFERRED EMBODIMENTS OF THE PRESENT INVENTION

The present embodiment provides an apparatus and method for identifying batteries with different thicknesses, specifically using the following scheme:

said apparatus comprising a buckle switch and a control circuit;

when a thin battery is mounted in said electronic device, the state of said buckle switch is ON; when a thick battery is mounted in said electronic device, the state of said buckle switch is OFF;

said control circuit identifies whether a thin battery or a thick battery is mounted in said electronic device according to the state of said buckle switch.

Wherein, said buckle switch comprises a buckle, a spring member and a switch device, one side of said buckle is provided with an arc-shaped contact surface in contact with the side surface of a battery body, and the other side is provided with a slot with a spring member; said spring member is respectively connected with said slot and said switch device.

Preferably, the mechanical part of said buckle switch consists of one or more buckles whose upper surface is arc and lower surface is planar (the side of said buckle has a slot with said spring member), a spring member, and a switch device connected to a motherboard, and said switch device may be a mechanical switch or a FPC (flexible printed circuit) switch.

Preferably, said buckle switch works as a single-pole double-throw switch in circuit connection and has two states, ON and OFF, wherein the state of ON is a state pulled high by the high level, and the state of OFF is a grounding state. The ON/OFF state of said buckle switch is determined by the relative positions of said battery and said buckle switch, the state information of said buckle switch is fed back to said baseband processing chip via said GPIO bus. After said baseband processing chip obtains the information of said state, it calls corresponding battery information to manage power management modules and manages said battery according to different states. When a thin battery is mounted in said terminal device, after the installation, said buckle is bounced up, and the state of said buckle switch is ON. When a thick battery is mounted in said terminal apparatus, the buckle is pressed down after the installation, and the state of said buckle switch is OFF.

When said battery is placed into said battery compartment from the top of said motherboard, one end of said battery contacts on the upper surface of said buckle, forces the arc-shaped surface retracted from the side into a side slot of said battery. When the battery thickness is small, through the thickness journey, the side buckle is no longer subject to force and pops out, the switch state is OFF; when the battery is relatively thick, through the thickness journey, the side buckle is forced in the still thick battery journey, thus will not pop out, and the switch state is ON.

Preferably, the switch device connecting to said motherboard have many forms, which can be a mechanically pressed touch switch, a FPC switch, a stylus switch, and so on. The connection methods can be different according to different switch forms. It can be that the switch is directly soldered on said motherboard; a metal contact point is set on said motherboard, an elastic pin on said switch is pressed to touch said contact point; or an elastic pin is set on said motherboard, and said elastic pin is pressed to touch said metal contact point on said switch.

Hereinafter with reference to the accompanying drawings, the embodiments of the present invention will be described in detail. It should be noted that, in the case of no conflict, the embodiments and features in the embodiments of the present application may be arbitrarily combined with each other.

In the following embodiments, the mobile terminal is taken as an example to describe a specific implementation of the present invention, but the invention scheme is not limited to be applied to mobile terminals, it can be similarly applied to other electronic devices such as laptops and tablet PCs.

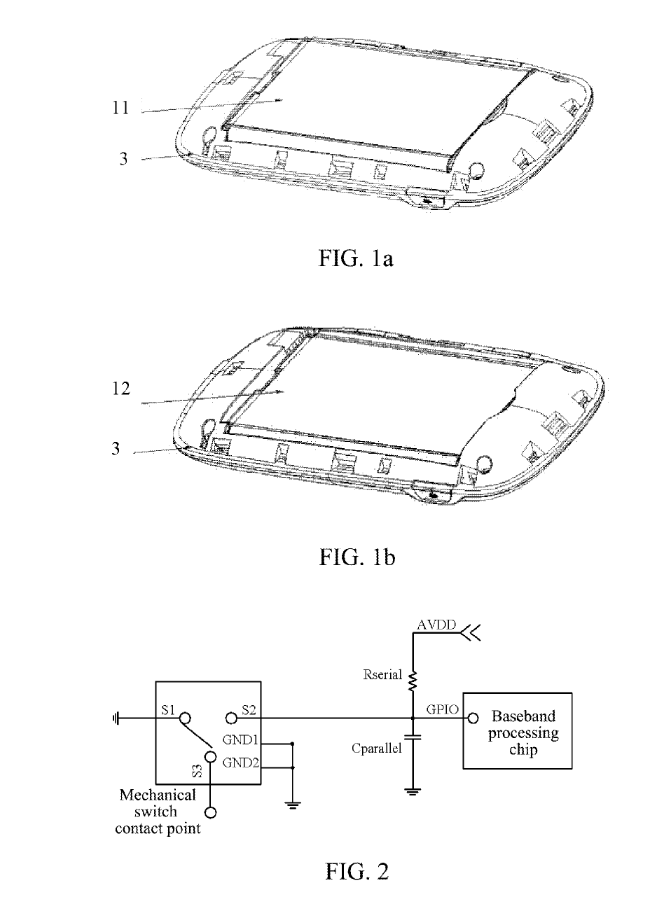

As shown in FIG. 1a and FIG. 1 b, the mobile terminal is taken as an example to describe the schematic diagrams of the batteries with different thicknesses: thin battery 11 and thick battery 12 being respectively assembled in the rear housing 3 of the same electronic device.

FIG. 2 shows a schematic diagram of a control circuit of a buckle switch in accordance with an embodiment of the present invention. As shown in FIG. 2, the basic working principle of the mechanical switch is: within the mechanical switch, it contains three working pins S1, S2 and S3, under normal circumstances, pin S3 is directly used to connect to the ground, and the definition of pins S1 and S2 is determined according to practical applications.

There are two switching states in accordance with the embodiment of the present invention:

state 1: S1 is in the state of being shorted to ground, S2 is still floating and connected to a GPIO port via a pull-up resistor network, S3 is a mechanical switch contact point, when said S3 is not triggered, the switch is in the state that said S1 is disconnected with S2;

state 2: S1 is in the state of being shorted to ground; when said S3 is triggered, it connects the pin S2 with the pin S1 of the switch; when triggered by said S3, said S2 changes from the floating state to the state of connecting with said S1, and is in the grounding state; said switch is in the state that said S1 and said S2 are touching.

Said control circuit only needs one state (high or low state) to make said baseband processing chip control the state of peripherals and achieve the corresponding functions. Under normal circumstances, a analog voltage AVDD (value is 2.8V) commonly used in the mobile phone is used at said GPIO (General Purpose Input Output) port, and a resistor Rserial is connected to the GPIO port in series to perform said pull-up processing method, meanwhile, a parallel capacitor Cparallel is set aside for filtering out some interference signals.

When the mechanical switch is in state 1, since said S2 is still floating, it is equivalent to an infinite ohm resistor in the circuit, and said equivalent infinite resistor and said Rserial consist in a resistor divider network, the voltage at the GPIO port and the AVDD voltage are the same, at this time said GPIO is a high level.

When said mechanical switch is in state 2, since said S2 is in the grounding state, it is equivalent to a zero ohm resistor in the circuit, when said zero ohm resistor and said Rserial consist into a resistor divider network, the voltage at said GPIO port is zero, at this time said GPIO is a low level.

The two states: high and low levels of said GPIO port respectively correspond to thick and thin two types of batteries, thus by judging the high or low level at the GPIO port on said baseband processing chip, the thick and thin type of said battery can be determined, thus achieving different power controls.

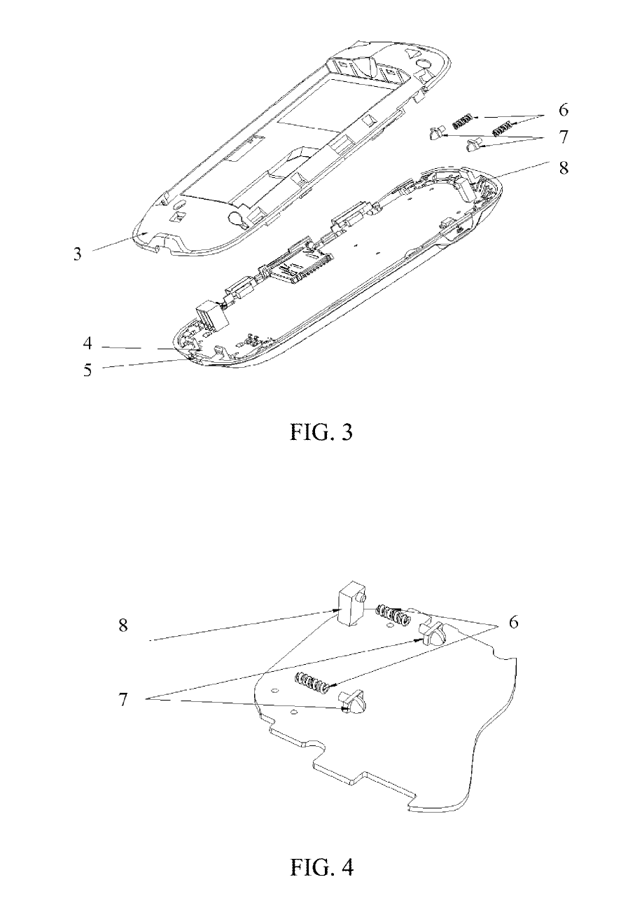

FIG. 3 shows an exploded diagram of an identification device with a buckle switch by taking the mobile terminal as an example, and said mobile terminal comprises motherboard 4, front housing 5 and rear housing 3, wherein, a buckle switch component is provided on said motherboard 4. There are two slots provided in the rear housing 3, and the buckle 7 of said buckle switch component is embedded in the rear housing 3 by slotting, and partially exposed on the surface, the upper arc-shaped surface of said buckle 7 is upward, the side of said buckle has a cylinder, in which spring 6 can be inserted, said spring 6 is connected to the switch device 8 connected on said motherboard (the method for said switch device 8 connecting with said motherboard can be soldering, screw fixing, or a combination of various methods).

When said buckle 7 is forced, it presses said spring 6 from the side, the cylinder of said buckle forces said switch device 8 to be pressed down; when said buckle 7 is not forced any longer, said spring 6 rebounds said buckle 7 outwardly, and said switching device 8 is not forced any longer and bounced up. Both in the thick and thin battery assemblies, the arc-shaped surface of said buckle 7 will be pressed to force it retracted inwardly.

FIG. 4 shows a schematic diagram of a buckle switch in accordance with an embodiment of the present invention. FIG. 4 takes two buckles for example, one buckle is connected with said switch device on said motherboard to play the roles of detecting said switch and fixing said battery, and the other one is connected with structural members to fix said battery. There is one cylinder at the side of said buckle, when the arc-shaped surface of the buckle receives a force, said cylinder presses said spring inwardly and presses said switch device, and said switch device changes from state 1 to state 2. When said battery is loaded and the device is powered on, said baseband processing chip detects the state of said switch device, if it is in said state 1, said baseband processing chip calls thin battery status information and manages said battery, if it is in said state 2, said baseband processing chip calls thick battery status information and manages said battery.

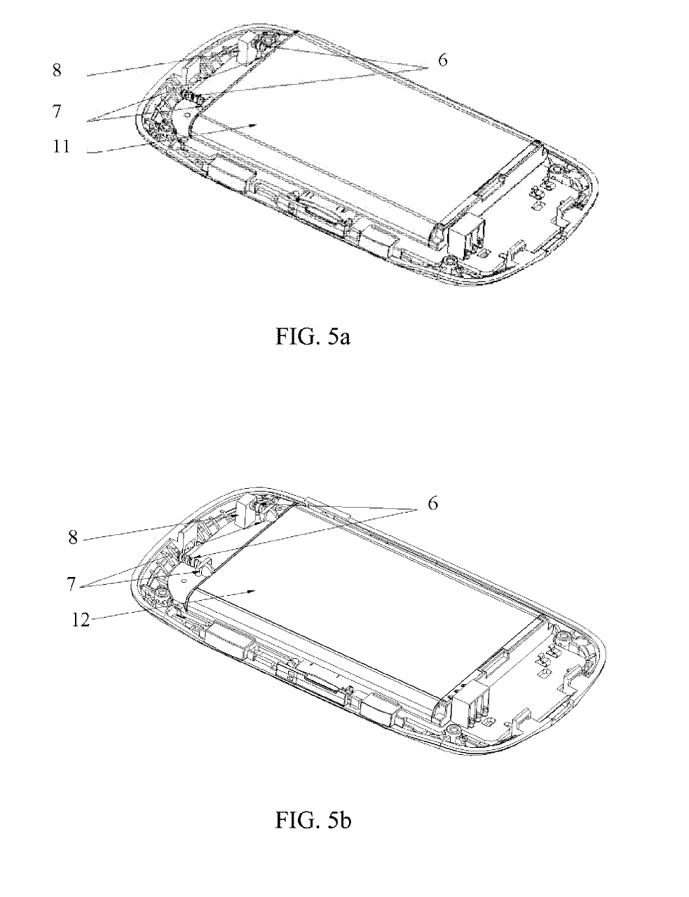

FIG. 5 shows an assembly diagram of assembling thick and thin batteries in an identification device with a buckle switch, the height of thin battery 12 is small, when said switch device 8 is no longer forced after the journey of the height of said thin battery, said buckle 7 buckles thin battery 12 so it does not fall out, said spring 6 rebounds said buckle 7 out, said switch device 8 is not forced to press down. The highness of said thick battery 11 is relatively large, said buckle 7 is keeping forced after the thick battery is buckled; said buckle 7 presses said spring 6 and presses said switch device 8 down, and said switch device 8 is pressed down by the force, and its state changes. In addition, FIG. 5 takes two buckles for example, one is connected with a switch device on the motherboard to fix said battery and detect said switch, and the other one is connected with a structural member to fix said battery.

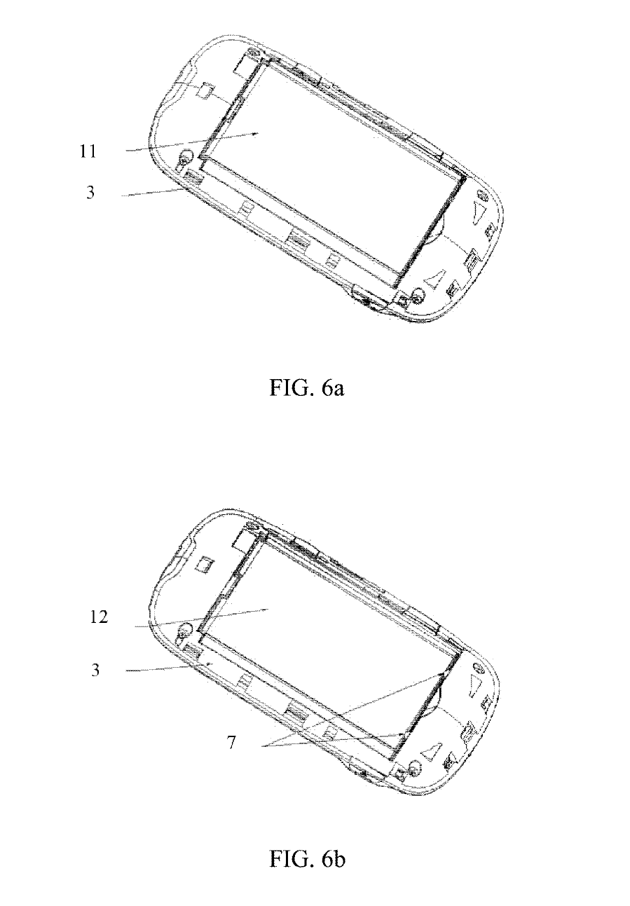

FIG. 6 is a schematic diagram of an assembly of a mobile terminal battery with a buckle switch identification device. Take a mobile terminal with two buckles for example, it can be seen that when the thin battery 12 is assembled, said buckle 7 first retracts and then pops out and buckles with said thin battery 12 after the assembly, at this time, the state of said switch is state 1; when the thick battery 11 is assembled, the buckle 7 retracts, and after the assembly, said buckle 7 does not pop up, at this time, the state of said switch is state 2.

In summary, the embodiments of the present invention combine the simple control circuit with the buckle switch to provide a structure that can accurately judge the thick and thin batteries, at the same time of being responsible for identification, said switch can also be used as a buckle structure to fix the thin battery, and a set of structural members can be used to batteries with different thicknesses; meanwhile, the corresponding battery information can be called to manage said batteries. The embodiment of the present invention is advantageous in that it has a simple structure and low cost, and can accurately judge the thick and think batteries in the electronic devices.

The above description is only preferred embodiments of the present invention and not intended to limit the present invention, and the present invention may also have a variety of other embodiments, without departing from the spirit and essence of the present invention, a person skilled in the art may make various corresponding changes and modifications based on the embodiments of the present invention, and these changes and modifications fall within the protection scope of the appended claims of the present invention.

Obviously, those skilled in the art should understand that, each abovementioned module or step of the present invention can be achieved with a general-purpose computing device, and they can be integrated on a single computing device or distributed in a network composed of a plurality of computing devices, alternatively, they may be implemented with program codes executable by a computing device, so that they can be stored in a storage means and executed by a computing device, moreover in some cases, the steps shown or described herein may be processed in a order different from what is shown here, or they are made into separate integrated circuit modules, or some of the modules or steps can be made into a single integrated circuit module to implement. Thus, the present invention is not limited to any specific combination of hardware and software.

### INDUSTRIAL APPLICABILITY

The apparatus in accordance with the embodiments of the present invention have a simple structure and low cost, and can accurately identify thick and thin batteries in electronic devices.

1. An apparatus for identifying batteries with different thicknesses, wherein, said apparatus comprises a buckle switch arranged at a position close to a battery compartment in an electronic device and a control circuit connected with said buckle switch;
said buckle switch being configured to: when a thin battery is mounted in said electronic device, said buckle switch's state is ON; when a thick battery is mounted in said electronic device, the state is OFF;
said control circuit being configured to: according to the state of ON/OFF of said buckle switch, identify whether a thin battery or a thick battery is mounted in said electronic device.

2. The apparatus of claim 1, wherein,
said buckle switch comprises a buckle, a spring member and a switch device, and said buckle is configured to be inserted into a housing of said electronic device by slotting, an arc-shaped contact surface is provided on one side of said battery compartment that is close to said buckle, and a slot is provided on the other side; said spring member is connected to said slot and said switch device respectively;
said buckle switch is configured as:
when a battery is loaded into said battery compartment, said battery contacting with said arc-shaped contact surface on one side of said buckle, and squeezing said spring member on the other side of said buckle; wherein, when the thick battery is loaded into said battery compartment, said buckle is pressed down, and said spring member is squeezed to trigger said slot to press said switch device down; when the thin battery is loaded into said battery compartment, said buckle is not pressed down, and a force of said spring member drives said switch device to pop up.

3. The apparatus of claim 1, wherein,
said control circuit comprises a baseband processing chip, and said buckle switch is connected with a general purpose input output (GPIO) port of said baseband processing chip, and said baseband processing chip is configured to determine the state of said buckle switch being ON or OFF according to a level state of said GPIO port.

4. The apparatus of claim 2, wherein,
a number of said buckles and said spring members is one or more.

5. The apparatus of claim 1, wherein,
said control circuit is further configured to, after identifying the battery mounted in said electronic device, respectively call appropriate power management modules to calculate and/or display power of said electronic device's power supply.

6. The apparatus of claim 2, wherein,
said switch device comprises: a mechanical press-contact switch, a flexible printed circuit (FPC) switch, or a stylus switch.

7. The apparatus of claim 2, wherein, said switch device is configured as:
being welded on said motherboard;
alternatively, an elastic pin on said switch device being pressed to touch a metal contact point of said motherboard;
alternatively, a metal contact point of said switch device being pressed and touched by an elastic pin set on said motherboard.

8. A method for identifying batteries with different thicknesses, comprising:
arranging a buckle switch connected with a control circuit at a position close to a battery compartment in an electronic device;
when a thin battery is mounted in said electronic device, a state of said buckle switch being ON; when a thick battery is mounted in said electronic device, the state of said buckle switch being OFF;
according to the state of ON/OFF of said buckle switch, said control circuit identifying whether a thin battery or a thick battery is mounted in said electronic device.

9. The method of claim 8, further comprising:
said control circuit comprising a baseband processing chip, and said buckle switch being connected with a GPIO port of said baseband processing chip, and said baseband processing chip determining the state of said buckle switch being ON or OFF according to a level state of said GPIO port.

10. The method of claim 8, wherein,
said buckle switch comprises a buckle, a spring member and a switch device, and said buckle is fitted in a housing of said electronic device by slotting, one side of the buckle that is close to said battery compartment is provided with an arc-shaped contact surface, and the other side is provided with a slot; said spring member is respectively connected with said slot and said switch device;
when said battery is loaded into said battery compartment, said battery contacts with said arc-shaped contact surface on one side of said buckle, and squeezes said spring member on the other side of said buckle;
wherein, when the thick battery is loaded into said battery compartment, said buckle is pressed down, said spring member is squeezed and triggers said slot to press said switch device down; when a thin battery is loaded into said battery compartment, said buckle is not pressed down, and a force of said spring member drives said switch device to pop up.

11. The method of claim 10, wherein,
said switch device is welded on said motherboard;
alternatively, a metal contact point is disposed on said motherboard, and an elastic pin on said switch device is pressed to touch said metal contact point;
alternatively, an elastic pin is set on said motherboard, and said elastic pin is pressed to touch a metal contact point of said switch device.

12. The method of claim 8, further comprising:
after said control circuit identifies the battery mounted in said electronic device, respectively calling appropriate power management modules to calculate and/or display power of said electronic device's power supply.

13. An electronic device, comprising the apparatus in claim 1.

14. The apparatus of claim 3, wherein,
a number of said buckles and said spring members is one or more.

15. The apparatus of claim 2, wherein,
said control circuit is further configured to, after identifying the battery mounted in said electronic device, respectively call appropriate power management modules to calculate and/or display power of said electronic device's power supply.

16. The apparatus of claim 3, wherein,
said control circuit is further configured to, after identifying the battery mounted in said electronic device, respectively call appropriate power management modules to calculate and/or display power of said electronic device's power supply.

17. The method of claim 9, further comprising:
after said control circuit identifies the battery mounted in said electronic device, respectively calling appropriate power management modules to calculate and/or display power of said electronic device's power supply.

18. The method of claim 10, further comprising:
after said control circuit identifies the battery mounted in said electronic device, respectively calling appropriate power management modules to calculate and/or display power of said electronic device's power supply.

19. An electronic device, comprising the apparatus in claim 2.

20. An electronic device, comprising the apparatus in claim 3.
